(19) United States
(12) Patent Application Publication
(10) Pub. No.: US 2009/0074356 A1
(43) Pub. Date: Mar. 19, 2009

(54) Waveguide Comprising an Anisotropic Diffracting Layer

(76) Inventors: Carlos I. Sanchez, Eindhoven (NL); Cornelis Wilhelmus Maria Bastiaansen, Montfort (NL); Dirk Jan Broer, Geldrop (NL); Michael James Escuti, Best (NL); Christianus Martinus Van Heesch, Eindhoven (NL)

Correspondence Address: NIXON & VANDERHYE, PC, 901 NORTH GLEBE ROAD, 11TH FLOOR, ARLINGTON, VA, 22203, US

(21) Appl. No.: 11/665,071

(22) PCT Filed: Oct. 14, 2005
(86) PCT No.: PCT/NL2005/000742

§ 371 Date: Apr. 3, 2008

(30) Foreign Application Priority Data
Oct. 15, 2004 (NL) PCT/NL2004/000731

(51) Int. Cl. G02B 6/26; G03F 1/00

(52) U.S. Cl. 385/31; 430/2

(57) ABSTRACT

The invention relates to an edge-lit slab waveguide equipped with a slanted anisotropic holographic layer, which couples out linearly polarized light. The invention further relates a new slanted anisotropic holographic layer suitable for use on the waveguide according to the invention, to a method to prepare such layer, and devices comprising the waveguide according to the invention.

The present invention relates to a novel waveguide, suitable for use in for example Liquid Crystal Displays (LCDs). Furthermore, the invention relates to a novel layer suitable for use on a waveguide, a method for making the waveguide and the layer, and devices comprising the waveguide according to the invention.

LCDs use illumination systems, which consume a large amount of energy. There is a need to increase the energy efficiency of these illumination systems. For example in case of portable equipment having an LCD, the efficiency of the illumination system greatly influences the battery life of the equipment and/or the brightness of the display.

There are two different types of illumination systems known for LCDs: backlight and frontlight systems.

Conventionally a backlight system is used in transmissive and/or transflective displays. Herein light coming from a source is coupled in a waveguide and emitted toward the viewer (scattering diffusers based on dot patterns or surface relief structures are most commonly used for the outcoupling). This light then passes through different optical layers such as for example polarizers, color filters, compensation layers and an electro-optical cell. In a typical transflective display, a semi-transparent mirror is used (transflector) which reflects ambient light and transmits light from a backlight. The illumination system is switched off in bright ambient light and visualization of the display is performed with the ambient light. In a dark environment, the backlight system is turned on to illuminate the display. The light efficiency of transflective displays is higher than that of transmissive displays. Nevertheless, the light efficiency of these conventional LCDs is still low due to, for instance, the light absorbing character of the different optical layers (polarizers, color filters).

Frontlight systems are typically incorporated into reflective LCDs. In reflective LCDs, ambient light is used very effectively to illuminate the display due to the presence of a full mirror (reflector). This results in more efficient light management in ambient light and an increase in brightness and/or battery life. However, current frontlights are equipped with light outcoupling structures which distort the image from the LCD. Moreover, such frontlights emit unpolarized (white) light towards the LCD and therefore still require absorbing polarizers and color filters, which cause a decrease in light efficiency.

The main challenges in the known configurations are to improve the management of light in order to reduce power consumption of the LCD and simultaneously generating excellent display characteristics with respect to, for instance, image quality. One option to save energy is to replace one of the polarizers and optionally the absorbing color filters with more light efficient counterparts.

U.S. Pat. No. 6,750,996 of Jagt et al discloses the use of a holographic layer as an alternative outcoupling system. The method discloses the formation of a slanted transmission volume hologram on top of the waveguide in transparent materials in such a way as to generate unidirectional, polarized and color-separated emission (FIG. 1).

Moreover, the slanted phase gratings are (almost) invisible in direct view and the light can be directed directly to the viewer. In other words, (additional) light out-coupling structures can be omitted thereby improving the perception of the display.

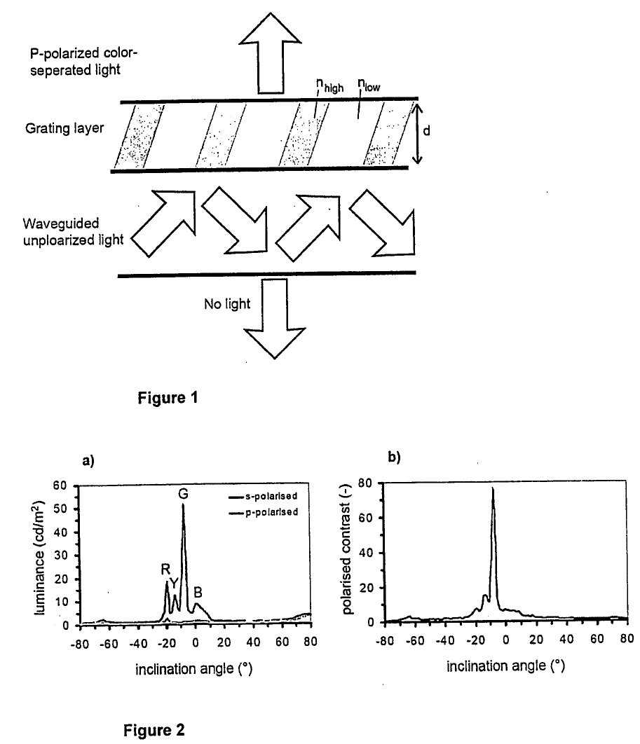

Large slant angles can be obtained in these holograms if the holograms are recorded in the so-called waveguiding mode, where the propagation direction of one of the laser beams of the holographic setup is perpendicular to the sensitive holographic layer while the propagation direction of the other beam is in the plane of the sensitive layer and interferes with the first beam, and a large polarization contrast can be obtained (FIG. 2b). The polarization contrast is defined as the ratio between the light intensities coupled out with respectively P and S polarization and measured near to the normal of the film. It is also shown (FIG. 2b) that the polarization contrast rapidly decreases at angles away from the normal which is a serious limitation of these holograms.

Recording in the waveguiding mode also has some practical disadvantages. Consequently, slanted holograms which are recorded in the transmission mode and which have a high polarization contrast were also investigated.

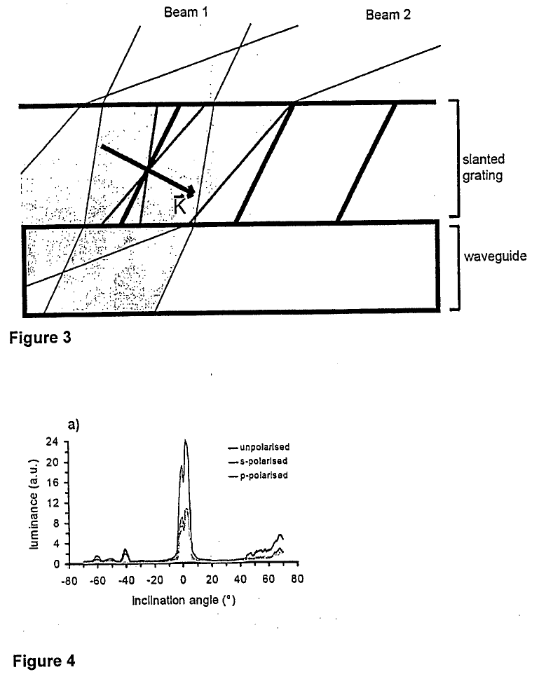

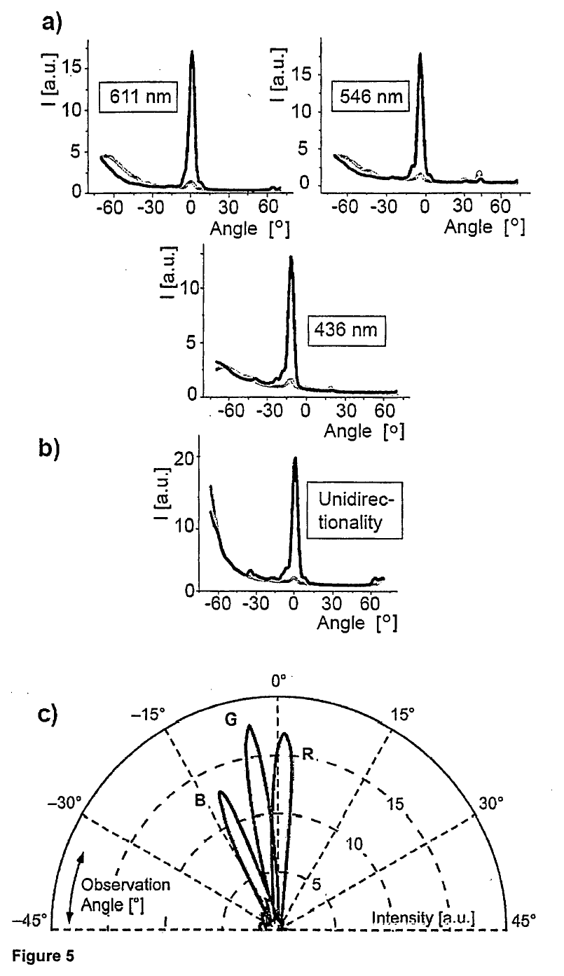

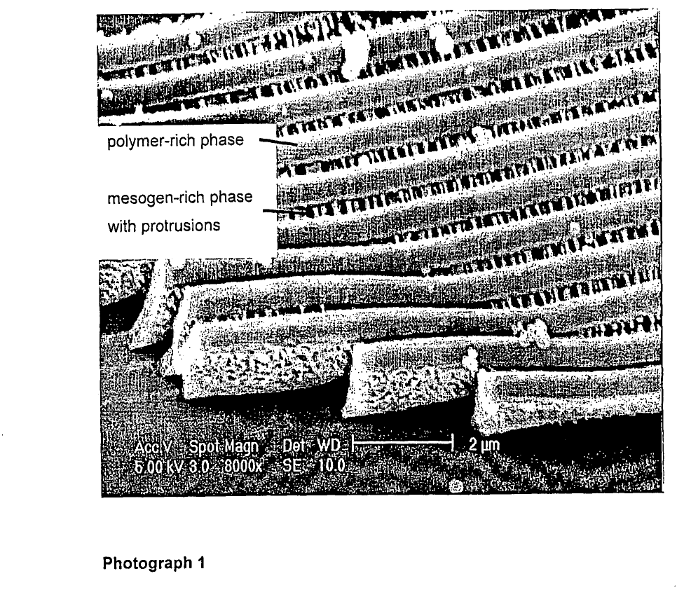

U.S. Pat. No. 6,750,996 furthermore discloses that in transmission mode it is preferable to record the grating with UV laser radiation (e.g. 351 nm) in such a way as to allow recording in a very simple and standard transmission holographic geometry (FIG. 3). The operation of this set-up and the generation of linearly polarized light however depends critically on the product (n_{high}−n_{low})(d/λ), where n_{high} and n_{low} are respectively the refractive index values of the high and low refractive index regions in the slanted hologram, d is the hologram layer thickness, and λ is the wavelength of operation. In case this product is large enough, the transmission hologram can be ‘over-modulated’ such that diffraction for one linear polarization is high while diffraction for the orthogonal polarization is close to zero. The disadvantage of this method is that it is difficult to find a high quality holographic material with a refractive index difference (n_{high}−n_{low}) high enough to permit thin layers to be used. For instance, using a more or less conventional recording material for holography results in a poor polarization contrast (FIG. 4) because the product (n_{high}−n_{low})(d/λ) is too low. Furthermore, the polarization contrast of the disclosed holograms is also intrinsically dependent on the wavelength (color) of the light used to illuminate the display. For instance, if white light is used for the illumination of the display, different polarization contrasts are obtained for blue, green and red light.

It is one of the objectives of the present invention, to provide an alternative solution to obtain a high polarization contrast being more energy efficient.

Surprisingly, this objective is reached by an edge-lit slab waveguide equipped with a slanted anisotropic holographic layer which couples out linearly polarized light.

It has been found that such layer can yield a relatively high polarization contrast, generally at least equal to or higher than 3, preferably at least equal to or higher than 5. The suitable polarization contrast depends on the application of the waveguide. In a portable telephone a polarization contrast of about 15-20 usually suffices, whilst for TV applications at least 200 is needed. It has been found that in combination with a clean-up (polarization) filter, polarization contrasts of at least 200 can easily be reached with the waveguide according to the invention without considerable loss in light intensity. Furthermore, it has been found that in using an anisotropic holographic layer, the properties of the layer are less dependent on the thickness of the used layer, thereby enabling the use of thin layers, which is another advantage of the waveguide according to the invention.

An additional advantage is that a wavelength (color) independent polarization contrast can be achieved.

Another additional advantage is that such holographic layers can be recorded in the transmission mode. A person skilled in the art knows how to prepare such layers not only with holographic techniques but also with lithographic techniques, i.e. making use of high-resolution light-blocking masks for the exposure rather than making use of interference or by making use of phase masks. Therefore, wherein in this description holography is used, a lithographic technique can also be applied.

The slanted anisotropic holographic layer can be either directly coated on the waveguide, or can be coated on a suitable substrate, for example a film. The waveguide can have many forms. It may comprise a waveguide substrate on which a volume hologram is laminated as a separate layer, or the volume hologram may be an integral part of the substrate. The volume hologram may be positioned on the side of the substrate facing to or facing away from the display or even embedded within the waveguiding substrate. The waveguide may comprise two or more mutually separate holograms each laminated onto or formed integral with the waveguiding substrate. The waveguide may be provided at opposite sides of the waveguiding substrate or stacked on top of one another. The waveguide may have a single entry side face or more than one entry side face. If there is more than one side face the volume hologram is configured to diffract waveguided light coupled in via any of the entry faces. In case there is one entry side face the waveguide may have a wedge shape in order to distribute the outcoupled light evenly over the total surface area.

Suitable materials for the substrate include glass and transparent ceramics. Preferably, however the substrate is made of a transparent polymer which may be thermosetting or thermoplastic. Suitable polymers may be (semi)-crystalline or amorphous. Examples include PMMA (polymethyl methacrylate), PS (polystyrene), PC (polycarbonate), COC (cyclic olefin copolymers), PET (polyethylene terephathalate), PES (polyether sulphone), but also crosslinked acrylates, epoxies, urethane and silicone rubbers. This substrate is then combined with the waveguide in a subsequent processing step. If the waveguide is an assembly of optically different members, layers and the like, with interfaces being formed where a boundary surface of a first member meets that of a second member, it may be necessary to use an adhesive layer to connect the boundary surface of such a first and second member. This provides the waveguide with mechanical integrity and/or avoids the occurrence of spurious reflections and optical inhomogeneities resulting from, for example, air trapped in spaces formed at interfaces. Examples of such adhesive layers and the conditions and circumstances under which use of such an adhesive is appropriate are well known to those skilled in the art. Therefore, where in the context invention two separate optical members are put together to form interface it is understood that the interface may also involve such an adhesive layer.

The present invention defines the wording waveguide to encompass only devices intended as an illumination device, whereby light is coupled in from the edges (edge-lit) and coupled out on the phase (side) of the slab waveguide.

Suitable materials for the waveguide are generally transparent for the light emitted by the waveguide. Suitable materials for the waveguide include glass and transparent ceramics. Preferably, however the waveguide is made of a transparent polymer which may be thermosetting or thermoplastic. Suitable polymers include thermosetting and thermoplastic polymers which may be (semi)-crystalline or amorphous. Examples include PMMA (polymethyl methacrylate), PS (polystyrene), PC (polycarbonate), COC (cyclic olefin copolymers), PET (polyethylene terephthalate), PES (polyether sulphone), but also crosslinked acrylates, epoxies, urethane and silicone rubbers.

In another embodiment of the invention, the waveguide according to the invention can couple out linearly polarized light of different wavelengths at different angles. This enables to substitute the color filters or to enhance the efficiency of generating color using a suitable microlens array that spatially separates into red-green-blue (RGB) pixels, thereby making the waveguide even more energy-efficient.

In another embodiment of the invention, the waveguide is capable of recycling the light that is not outcoupled. One can achieve this in ways known to the person skilled in the art, for example from U.S. Pat. No. 6,750,996. This embodiment will have an even higher light efficiency, since also the light that initially does not have the right polarization direction is modulated to the other (desired) polarization direction and can then be outcoupled (polarization modulation). Alternatively, the light that initially does not have the right wavelength (color) can be redirected to another pixel and can then be outcoupled (color modulation). It is also possible to combine polarization modulation and color modulation in one embodiment.

In another embodiment of the invention, the waveguide is equipped with a slanted anisotropic holographic layer based on at least one reactive monomer and at least one mesogen, wherein the mesogen is in an aligned state after polymerization. The monomer may be a single compound or a mixture of compounds. The mesogen may be a single compound or a mixture of compounds. Preferably the mesogen contains at least one reactive mesogen, this is a compound that comprises at least one reactive group.

In a further embodiment of the invention, an edge-lit slab waveguide is equipped with a slanted anisotropic holographic layer which couples out linearly polarized light, wherein the layer is obtained by polymerization of a mixture of at least one reactive monomer and a mesogen, and wherein the mesogen is in an aligned state. Preferably, the reactive monomer comprises at least a polyfunctional acrylate or methacrylate compound. Preferably, the mesogen comprises at least one compound having a polymerizable group. More preferably, the mesogen comprises at least one compound having a cationically polymerizable group. Even more preferably, the mesogen comprises at least one compound having an epoxy, oxetane or vinylether group.

Such layer capable of coupling out linearly polarized light is new and is also subject of the present invention. U.S. Pat. No. 6,750,996 discloses an isotropic layer and from Boiko et al (Optics Letters, 2002, Vol 27, no 19, pg 1717-1719) a slanted anisotropic holographic grating is known. The latter however is only suitable in transmission of light, not for outcoupling of polarized light. Furthermore, no mention is made regarding use of such layer on an edge-lit slab waveguide. Surprisingly, it was found that a slanted anisotropic holographic layer based on at least one reactive monomer and at least one mesogen, in which the mesogen is in an aligned state after polymerization, is capable of coupling out linearly polarized light. It can for example be used on an edge-lit slab waveguide in order to increase the light efficiency and thus decrease power use.

The term ‘reactive monomers’ encompasses any compound that polymerizes spontaneously or in combination with a suitable (polymerization) initiator, or in combination with suitable radiation. Free radical initiators or cationic initiators are often preferred. Preferably the monomers are molecules containing a reactive group of the following classes: vinyl, acrylate, methacrylate, epoxy, oxethane, vinylether, thiol-ene or hydroxy.

The reactive monomer can have one or more reactive groups per molecule. The reactive groups may be the same or different. In a preferred embodiment at least one polyfunctional monomer having more than one reactive group is used. This has the advantage that upon polymerization a polymer network is formed. This has beneficial effects with respect to material properties of the layer (for example scratch resistance, modulus, elongation at break, Izod and flexibility). The presence of a reactive monomer having more then one reactive group also increases the speed of polymerization thereby decreasing the time to record the hologram.

Examples of reactive monomers having at least two reactive groups per molecule include monomers containing (meth)acryloyl groups such as trimethylolpropane tri(meth)acrylate, pentaerythritol (meth)acrylate, ethylene glycol di(meth)acrylate, tetraethylene glycol di(meth)acrylate, polyethylene glycol di(meth)acrylate, 1,4-butanediol di(meth)acrylate, 1,6-hexanediol di(meth)acrylate, neopentyl glycol di(meth)acrylate, polybutanediol di(meth)acrylate, tripropyleneglycol di(meth)acrylate, glycerol tri(meth)acrylate, phosphoric acid mono- and di(meth)acrylates, C₇-C₂₀ alkyl di(meth)acrylates, trimethylolpropanetrioxyethyl (meth)acrylate, tris(2-hydroxyethyl)isocyanurate tri(meth)acrylate, tris(2-hydroxyethyl)isocyanurate di(meth)acrylate, pentaerythritol tri(meth)acrylate, pentaerythritol tetra(meth)acrylate, dipentaerythritol monohydroxy pentacrylate, dipentaerythritol hexacrylate, tricyclodecane diyl dimethyl di(meth)acrylate and alkoxylated versions, preferably ethoxylated and/or propoxylated, of any of the preceding monomers, and also a di(meth)acrylate of a diol which is an ethylene oxide or propylene oxide adduct to bisphenol A, di(meth)acrylate of a diol which is an ethylene oxide or propylene oxide adduct to hydrogenated bisphenol A, epoxy (meth)acrylate which is a (meth)acrylate adduct to bisphenol A of diglycidyl ether, diacrylate of polyoxyalkylated bisphenol A, and triethylene glycol divinyl ether, adduct of hydroxyethyl acrylate, isophorone diisocyanate and hydroxyethyl acrylate (HIH), adduct of hydroxyethyl acrylate, toluene diisocyanate and hydroxyethyl acrylate (HTH), and amide ester acrylate.

Examples of suitable monomers having only one reactive group per molecule include monomers containing a vinyl group, such as N-vinyl pyrrolidone, N-vinyl caprolactam, vinyl imidazole, vinyl pyridine; isobornyl (meth)acrylate, bornyl (meth)acrylate, tricyclodecanyl (meth)acrylate, dicyclopentanyl (meth)acrylate, dicyclopentenyl (meth)acrylate, cyclohexyl (meth)acrylate, benzyl (meth)acrylate, 4-butylcyclohexyl (meth)acrylate, acryloyl morpholine, (meth)acrylic acid, 2-hydroxyethyl (meth)acrylate, 2-hydroxypropyl (meth)acrylate, 2-hydroxybutyl (meth)acrylate, methyl (meth)acrylate, ethyl (meth)acrylate, propyl (meth)acrylate, isopropyl (meth)acrylate, butyl (meth)acrylate, amyl (meth)acrylate, isobutyl (meth)acrylate, t-butyl (meth)acrylate, pentyl (meth)acrylate, caprolactone acrylate, isoamyl (meth)acrylate, hexyl (meth)acrylate, heptyl (meth)acrylate, octyl (meth)acrylate, isooctyl (meth)acrylate, 2-ethylhexyl (meth)acrylate, nonyl (meth)acrylate, decyl (meth)acrylate, isodecyl (meth)acrylate, tridecyl (meth)acrylate, undecyl (meth)acrylate, lauryl (meth)acrylate, stearyl (meth)acrylate, isostearyl (meth)acrylate, tetrahydrofurfuryl (meth)acrylate, butoxyethyl (meth)acrylate, ethoxydiethylene glycol (meth)acrylate, benzyl (meth)acrylate, phenoxyethyl (meth)acrylate, polyethylene glycol mono(meth)acrylate, polypropylene glycol mono(meth)acrylate, methoxyethylene glycol (meth)acrylate, ethoxyethyl (meth)acrylate, methoxypolyethylene glycol (meth)acrylate, methoxypolypropylene glycol (meth)acrylate, diacetone (meth)acrylamide, beta-carboxyethyl (meth)acrylate, phthalic acid (meth)acrylate, isobutoxymethyl (meth)acrylamide, N,N-dimethyl (meth)acrylamide, t-octyl (meth)acrylamide, dimethylaminoethyl (meth)acrylate, diethylaminoethyl (meth)acrylate, butylcarbamylethyl (meth)acrylate, n-isopropyl (meth)acrylamide fluorinated (meth)acrylate, 7-amino-3,7-dimethyloctyl (meth)acrylate, N,N-diethyl (meth)acrylamide, N,N-dimethylaminopropyl (meth)acrylamide, hydroxybutyl vinyl ether, lauryl vinyl ether, cetyl vinyl ether, 2-ethylhexyl vinyl ether. It also comprises compounds represented by the following formula (I)

CH₂═C(R⁶)—COO(R⁷O)ₘ—R⁸ (I)

wherein R⁶ is a hydrogen atom or a methyl group; R⁷ is an alkylene group containing 2 to 8, preferably 2 to 5 carbon atoms; and m is an integer from 0 to 12, and preferably from 1 to 8; R⁸ is a hydrogen atom or an alkyl group containing 1 to 12, preferably 1 to 9, carbon atoms; or, R⁸ is a tetrahydrofuran group, comprising alkyl group with 4-20 carbon atoms, optionally substituted with one or more alkyl groups with 1-2 carbon atoms; or R⁸ is a dioxane group-comprising alkyl group with 4-20 carbon atoms, optionally substituted with methyl groups; or R⁸ is an aromatic group, optionally substituted with one or more C₁-C₁₂ alkyl groups, preferably C₈-C₉ alkyl groups, and alkoxylated aliphatic monofunctional monomers, such as ethoxylated isodecyl (meth)acrylate, ethoxylated lauryl (meth)acrylate.

Also oligomers can be suitable for use as a reactive monomer. Examples of such oligomers are aromatic or aliphatic urethane acrylates or oligomers based on phenolic resins (ex. bisphenol epoxy diacrylates), and any of the above oligomers chain extended with ethoxylates. Urethane oligomers may for example be based on a polyol backbone, for example polyether polyols, polyester polyols, polycarbonate polyols, polycaprolactone polyols, acrylic polyols. These polyols may be used either individually or in combinations of two or more. There are no specific limitations to the manner of polymerization of the structural units in these polyols. Any of random polymerization, block polymerization, or graft polymerization is acceptable. Examples of suitable polyols, polyisocyanates and hydroxylgroup-containing (meth)acrylates for the formation of urethane oligomers are disclosed in WO 00/18696, which is incorporated herein by reference.

Further possible compounds that may be used as a reactive monomer are moisture curable isocyanates, moisture curable mixtures of alkoxy/acyloxy-silanes, alkoxy titanates, alkoxy zirconates, or urea-, urea/melamine-, melamine-formaldehyde or phenol-formaldehyde (resol, novolac types), or radical curable (peroxide- or photo-initiated) ethylenically unsaturated mono- and polyfunctional monomers and polymers, e.g. acrylates, methacrylates, maleate/vinyl ether), or radical curable (peroxide- or photo-initiated) unsaturated compounds e.g. maleic or fumaric, polyesters in styrene and/or in methacrylates.

Also combinations of any of the above materials may be used. Combinations of compounds that together may result in the formation of a crosslinked phase and thus in combination are suitable to be used as the reactive monomer are for example carboxylic acids and/or carboxylic anhydrides combined with epoxies, acids combined with hydroxy compounds, especially 2-hydroxyalkylamides, amines combined with isocyanates, for example blocked isocyanate, uretdion or carbodiimide, epoxies combined with amines or with dicyandiamides, hydrazinamides combined with isocyanates, hydroxy compounds combined with isocyanates, for example blocked isocyanate, uretdion or carbodiimide, hydroxy compounds combined with anhydrides, hydroxy compounds combined with (etherified) methylolamide (“amino-resins”), thiols combined with isocyanates, thiols combined with acrylates or other vinylic species (optionally radical initiated), acetoacetate combined with acrylates. When cationic crosslinking is used epoxy compounds with epoxy or hydroxy compounds are suitable.

In a preferred embodiment the reactive monomer comprises compounds having acrylate or methacrylate functional groups. Examples of such reactive monomers are highly reactive (meth)acrylates or mixtures commercially available for the preparation of Polymer Dispersed Liquid Crystals (PDLCs). An example of such preferred mixture is a mixture of mono- and triacrylates such as PN393® of Merck.

The term ‘liquid crystal’ or ‘mesogen’ is used to indicate materials or compounds comprising one or more (semi-) rigid rod-shaped, banana-shaped, board-shaped or disk-shaped mesogenic groups, i.e. groups with the ability to induce liquid crystal phase behavior. Liquid crystal compounds with rod-shaped or board-shaped groups are also known in the art as ‘calamitic’ liquid crystals. Liquid crystal compounds with a disk-shaped group are also known in the art as ‘discotic’ liquid crystals. Hereinafter the terms ‘liquid crystal’ or ‘mesogen’ are used interchangeably, unless specified otherwise. The compounds or materials comprising mesogenic groups do not necessarily have to exhibit a liquid crystal phase themselves. It is also possible that they show liquid crystal phase behavior only in mixtures with other compounds used in the layer, or after the polymerization into the definite layer as present on the waveguide according to the invention.

The mesogen can be a reactive mesogen or a non-reactive mesogen. Examples of suitable non-reactive mesogens are those available from Merck, for example as described in their product folder Licristal® Liquid Crystal Mixtures for Electro-Optic Displays (May 2002) whose contents is herein incorporated by reference regarding non-reactive mesogens. Preferably the ones regarding use in PDLCs are used for example halogenated mesogens, such as for example TL205 (Merck, Darmstadt) or cyanobiphenyls, such as for example E7 (Merck, Darmstadt). Also mixtures of non-reactive mesogens can be used.

Examples of suitable reactive mesogens are those comprising acrylate, methacrylate, epoxy, oxethane, vinyl-ether, styrene, hydroxy and thiol-ene groups. Suitable examples are for example described in WO04/025337 whose contents is herein incorporated by reference regarding reactive mesogens, referred in WO04/025337 as polymerizable mesogenic compounds and polymerizable liquid crystal materials.

Examples representing especially useful mono- and direactive polymerisable mesogenic compounds are shown in the following list of compounds, which should, however, be taken only as illustrative and is in no way intended to restrict, but instead to explain the present invention:

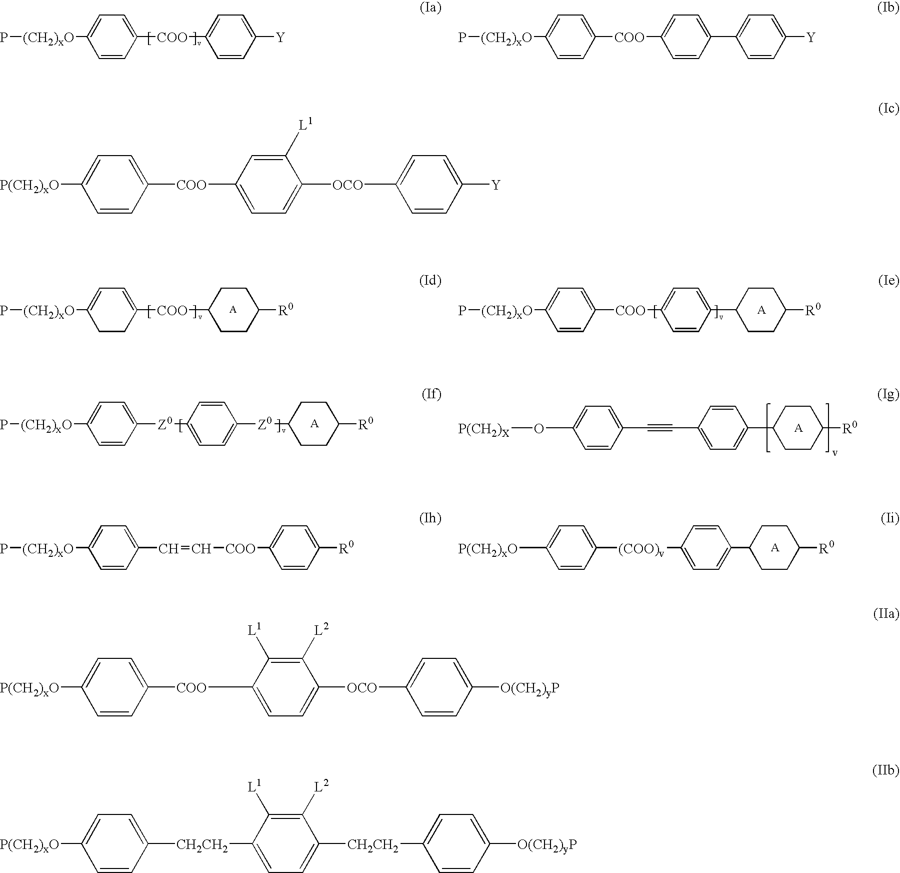

In the above formulae, P is a polymerizable group, preferably an acryl, methacryl, vinyl, vinyloxy, propenyl ether, epoxy or styryl group, x and y are each independently 1 to 12, A is 1,4-phenylene that is optionally mono-di or trisubstituted by L¹ or 1,4-cyclohexylene, v is 0 or 1, Z⁰ is —COO—, —OCO—, —CH₂CH₂—, —C≡C— or a single bond, Y is a polar group, R⁰ is an non-polar alkyl or alkoxy group, and L¹ and L² are each independently H, F, Cl, CN or an optionally halogenated alkyl, alkoxy, alkylcarbonyl, alkoxycarbonyl or alkoxycarbonyloxy group with 1 to 7 C atoms.

The term ‘polar group’ in this connection means a group selected from F, Cl, CN, NO₂, OH, OCH₃, OCN, SCN, an optionally fluorinated carbonyl or carboxyl group with up to 4 C atoms or a mono-oligo- or polyfluorinated alkyl or alkoxy group with 1 to 4 C atoms. The term ‘non-polar group’ means an alkyl group with 1 or more, preferably 1 to 12 C atoms or an alkoxy group with 2 or more, preferably 2 to 12 C atoms.

Polymerization of the polymerizable LC material can be achieved for example by exposing it to heat or actinic radiation. Actinic radiation means irradiation with light, like UV light, IR light or visible light, irradiation with X-rays or gamma rays or irradiation with high energy particles, such as ions or electrons. Preferably polymerisation is carried out by UV irradiation. Also mixtures of reactive mesogens can be used (Merck Reactive Mesogens, Brighter clearer communication, 2004). Preferably the reactive mesogen comprises at least a compound having a cationically polymerizable group.

Also mixtures of reactive and non-reactive mesogens can be used. In case of a mixture, substantially all mesogens used are preferably in an aligned state in the final layer. It is preferred that more then 80% of the mesogens are in an aligned state in the final layer.

Examples of suitable combinations between monomer and mesogen are PN393 and TL205 (both from Merck, Darmstadt).

In a preferred embodiment of the invention the difference between the ordinary refractive index of the mesogen (n_{o,m}) and the isotropic refractive index of the polymer (n_{iso,p}) is less than 0.01, even more preferably less than 0.005. Most preferably n_{o,m} is matched with n_{iso,p} in the state wherein polarized light is outcoupled.

In another preferred embodiment of the invention the difference between the extra-ordinary refractive index of the mesogen (n_{e,m}) and the isotropic refractive index of the polymer (n_{iso,p}) is less than 0.01, even more preferably less than 0.005. Most preferably, n_{e,m} is matched with n_{iso,p} in the state wherein polarized light is outcoupled.

In one embodiment of the invention, the layer is based on at least one reactive monomer and at least one reactive mesogen. From the prior art, such layer is not known. An advantage of comprising at least one reactive mesogen is an increased mechanical stability of the layer.

In another embodiment of the invention, the layer is based on at least one reactive monomer and at least one non-reactive mesogen in which the orientation of the non-reactive mesogen can be switched with an external field. Switching the orientation of the mesogen can be achieved in different ways, for example by use of an electric field, a magnetic field, and/or light. If light is used, photochromic additives are preferably added. The waveguide comprising the layer according to the invention could for example be equipped with layers for electrical addressing (active or passive matrix). In this specific embodiment, it is sometimes preferred to use mesogen mixtures comprising non-reactive and reactive mesogens to enhance response times. This can be of importance for certain applications such as laptops, desktops and television.

In case of use of at least one non-reactive mesogen (either only non-reactive or in combination with a reactive mesogen), the waveguide comprising the layer according to the invention will be switchable. Preferably, the waveguide is switchable between a light outcoupling (bright) state and a non-light-outcoupling (dark) state. In a preferred embodiment a high intensity contrast (ratio between the intensities transmitted by the display in the bright and dark state and measured at angles near to the normal) is obtained between the light outcoupling (bright) state and the non-light-outcoupling (dark) state and in which the bright state has a polarization contrast of at least 3, preferably at least 5. Generally, a high intensity contrast is a contrast of at least 5, more preferably at least 20 and even more preferably at least 100.

A switchable waveguide according to the invention can for example be used in switchable back and frontlights hereby obtaining an additional gain in energy efficiency. When the waveguide is made to couple out light locally by the use of patterned electrodes, it can be used in for example a dynamic backlight, for decreasing motion artifacts and increasing the dynamic contrast. For decreasing motion artifacts based on the so-called sample-and-hold problem, which is related to the way information is refreshed in a liquid crystal display, a striped electrode pattern is needed and the light outcoupling configuration is scanned over the screen with a frequency similar to the refreshing rate of the liquid crystal display, that is to say for instance 50, 80 or 100 Hz. Though the fact that light is outcoupled only locally, still a bright image can be generated because (1) all the light from the lamp system, which is for instance a cold cathode fluorescent lamp or a light emitting diode, which is coupled into the waveguide is coupled out locally with a high intensity rather than be distributed over the total area with a low intensity, and (2) because light has become polarized, less light is lost in the polarizing filter of the display. The scanning frequency of the waveguide is such that the viewer experiences this as a light source continuous in time. An additional advantage of such a dynamic display is that the luminance of the back or front light is equal over the total surface area and that no additional measures are needed to distribute the light evenly, such as a gradient in scattering features or a wedge-shape waveguide. The dynamic contrast of the display can be improved by application of an electrode matrix with orthogonal stripes of electrodes below and above the grating structure. By multiplexing the grating can be brought in a condition that light is coupled out locally, for instance in order to highlight a part of the display that represents a bright area (sun, sky, etc) and to shade the light in a darker part of the image. Of course, improvement of motion artifacts by scanning and improvement of the dynamic contrast can be combined.

The slanted anisotropic holographic layer can be made by polymerization of the reactive monomer and the mesogen.

Upon polymerization of the reactive monomer, phase separation takes place and a multi-phase system is formed comprising of a polymer-rich phase and a mesogen-rich phase. Surprisingly, this phase separation allows alignment of the mesogen. It is not excluded that the phases comprise protrusions of one phase into the other phase, sometimes even bridging through the other phase to the next similar phase for example protrusions of the polymer through the mesogen-rich phase. The protrusions may have a fiber-, ribbon- or tape-like geometry. Photograph 1 shows a SEM picture of an example of such geometry.

Furthermore, this invention relates to a new method of preparing the slanted anisotropic holographic layer according to the invention by polymerization. Examples of suitable polymerization methods are thermal, electron beam, electromagnetic radiation (UV, visible and NEAR IR) or photo-polymerization. Photo-polymerization can be induced by either visible or by UV light. Preferably, UV light is used to record the hologram since it allows recording in the transmission mode and outcoupling light in a visible wavelength region (see Jagt et al, U.S. Pat. No. 6,750,996). The UV-polymerization may take place through a free-radical mechanism, a cationic mechanism or a combination of any of them. In case of photo-polymerization, preferably a suitable photo-initiator is present in the reaction mixture.

Any known photo-initiator known may be used in the process according to the invention. The layer can be produced by polymerizing the reactive monomer and optionally the reactive mesogen using the same or a different polymerization method.

In case of the presence of a reactive mesogen, preferably different polymerization methods, mechanisms or different reactive end-groups are used. The advantage is that a better phase separation can be reached, due to the possibility of polymerizing the different compounds at a different point in time.

Preferably, the method according to the invention comprises the steps of preparing a mixture comprising at least one reactive monomer and at least one reactive mesogen, whereby the reactive monomer is polymerized using one polymerization method and that the mesogen which is polymerized by use of another polymerization method. More preferably, at least one polymerization is photo-polymerization.

The reactive monomer can be polymerized before or after the reactive mesogen is polymerized. Preferably, the reactive monomer is polymerized before the polymerization of the reactive mesogen. This way the alignment of the reactive mesogen can be adapted whilst already a more robust grating structure has been established.

In one embodiment of the invention the reactive monomer is reacted using UV or visible light, whilst the reactive mesogen is polymerized differently, for instance, thermally. In a second embodiment, two different UV-polymerization mechanisms are used (resp. free-radical and cationic). For instance, a (meth)acrylate based reactive monomer is polymerized first using a (fast) free radical initiator and a cationic (slow) UV-initiator is employed to polymerize an epoxy-based reactive mesogen afterwards with a flood (homogeneous) exposure.

In a preferred embodiment of this invention the polymerization of the monomer is induced using a photo-initiator, where after the hologram is recorded using UV light in a configuration not requiring additional coupling elements.

In another embodiment of the invention the reactive mesogen is reacted using UV of visible light, whilst the reactive monomer is polymerized differently.

A preferred method for making a slanted anisotropic holographic layer comprises the steps of:
a) providing a mixture of at least one reactive monomer and a reactive mesogen,
b) making a layer of the mixture,
c) applying UV radiation in order to at least partially polymerize the reactive monomer into a slanted transmission grating,
d) applying a subsequent thermal or UV exposure to further polymerize the reactive mesogen and (optional) residual unreacted monomer.

Preferably the UV radiation in step c is applied using laser split into a two beam transmission mode geometry. Preferably the reactive monomer comprises at least a polyfunctional acrylate or methacrylate compound. Preferably the reactive mesogen comprises at least a compound having a cationically polymerizable group. Preferably the layer of the mixture is prepared by filling the mixture into a cell having one or more spacers of a defined thickness.

The anisotropic layer obtainable by the method according to the invention is also part of the present invention, since this layer has different properties than the anisotropic layers obtained by methods known in the prior art.

The invention further relates to a frontlight, a backlight, display or optical device comprising the waveguide according to the invention.

The waveguide according to the invention makes the use of a separate polarizer unneeded, thereby simplifying the display design and, because of the higher efficiency, saving electrical power. Alternatively the layer on the waveguide can be used to increase brightness of the display with the same amount of power used in a conventional display. In certain equipment, the contrast ratio can even be enlarged by combining the waveguide according to the invention with a clean-up polarizer.

The invention is hereafter elucidated by the following non-limiting examples of suitable embodiments and comparative experiments.

### Comparative Experiment A

A mixture of 49.5 wt % cyclohexyl methacrylate, 49.5 wt % polystyrene (M_{w}=45,000 g/mole) and 1 wt % UV-initiator (1-hydroxycyclohexylphenylketone) was coated between 2 glass substrates having a 150 μm spacing. The substrate was exposed using recording in the waveguiding mode as described by Jagt with UV-beam (angles of 18.4 and 32.8 degrees to create a holographic film which couples out waveguided light from a CCFL at near normal angles). The luminance of the outcoupled light was measured using a CCD-spectrometer (Autronic, CCD-spect-2). FIG. 2a shows the luminance as a function of angle for both polarization directions and FIG. 2b shows the polarization contrast of the film. The polarization contrast has a maximum of 80 near the normal and declines very quickly at angles away from the normal.

### Comparative Experiment B

A mixture of 49.5 wt % cyclohexyl methacrylate, 49.5 wt % polystyrene (M_{w}=45,000 g/mole) and 1 wt % UV-initiator (1-hydroxycyclohexylphenylketone) was coated between 2 glass substrates having a 50 μm spacing. The substrate was exposed to the 351 nm line of an Ar ion laser (25 mW/cm² each beam) using a 2-beam transmission mode recording geometry (FIG. 3). A grating was recorded with a 371.2 nm pitch and 43 degrees slant angle. The luminance of the outcoupled light was measured using a CCD-spectrometer (Autronic, CCD-spect-2). The resulting polarized angular luminance distribution (FIG. 4) shows no significant difference in diffraction efficiency of both polarization directions. The highest polarization contrast in the high intensity region is 1.25. The low polarization contrast is due to the mismatch of layer thickness and refractive index difference (n_{high}−n_{low}) of the grating.

### EXAMPLE 1

A mixture of PN393 pre-polymer (2-ethylhexylacrylate monomer and trimethylolpropane triacrylate cross-linker, with UV sensitive photo-initiator, from Merck), TL205 nematic LC (a mixture of halogenated bi- and ter-phenyls with aliphatic tails of lengths two to five carbons from Merck with (nₒ, nₑ)=(1.527, 1.745) at 589 nm, 20° C.), and an additional cross-linker trimethylolpropane trimethacrylate (Aldrich) was prepared with a wt % ratio of 40/50/10, respectively.

A cell with 7 μm spacers was filled with the mixture and exposed with the 351 nm line of an Ar ion laser (25 mW/cm² each beam) using a 2-beam transmission mode recording geometry with angles at +71.5 and +13.4 degrees. A subsequent uniform exposure of 30 minutes to 365 nm completes the polymerization of the residual acrylates. In this way a slanted transmission grating with period Λ≈450 nm and slant angle φ_{G}=23° was recorded in films of thickness d=7 μm. The luminance of the outcoupled light from a CCFL was measured using a CCD-spectrometer (Autronic, CCD-spect-2). A polarization contrast of respectively 13, 12, and 8 for red (611 nm), green (546 nm), and blue (436 nm) light is obtained at near normal angles (FIG. 5a). Contrary to the films described in comparative experiment A a high polarization contrast is obtained for a broad wavelength range. In FIG. 5b, it is shown that the light emission is highly unidirectional which is a major advantage especially in frontlight applications. In FIG. 5c, it is shown that the different colors of light are emitted at slightly different angles. This phenomenon can be used (see Jagt et al, U.S. Pat. No. 6,750,966) to enhance the efficiency of the color filters.

### EXAMPLE 2

A mixture of PN393 pre-polymer (2-ethylhexylacrylate monomer and trimethylolpropane triacrylate cross-linker, with UV sensitive photo-initiator, from Merck), liquid-crystalline diepoxide 4-[(2,3-epoxy-propenyl)oxy]phenyl 4-[(2,3-epoxypropenyl)oxy]benzoate with 1 wt % cationic diaryliodonium salt, and an additional cross-linker trimethylolpropane trimethacrylate (Aldrich) was prepared with a wt % ratio of 40/50/10, respectively.

A cell with 18 μm spacers was filled with the mixture and exposed to the 351 nm line of an Ar ion laser (25 mW/cm² each beam) using a 2 beam transmission geometry with angles at +42.5 and −42.5 degrees. A subsequent uniform exposure of 60 minutes to 365 nm completed the polymerization of the residual acrylates and polymerized the liquid-crystalline diepoxide. In this way a fully polymeric film was formed with a slanted grating with period Λ≈450 nm. A high refractive index modulated (˜0.005) solid film was obtained showing a phase separation of reactive monomer (acrylates) and reactive mesogen (liquid-crystalline diepoxide). The polymer grating could be pealed of the glass substrates and a fully polymerized and flexible film was obtained. Moreover, the film exhibited a polarization contrast of 7 at 546 nm.

FIG. 1

Operation of a backlight or frontlight equipped with a hologram according to Jagt et al. (U.S. Pat. No. 6,750,996); unpolarized light is coupled into the waveguide slab from the edge, is emitted as polarized and color-separated light in one direction normal to the backlight with the use of a grating film.

FIG. 2

(a) Measured angular distribution of P and S polarized emission of a grating described by comparative experiment A. Indicating the color separation of the light emitted by a CCFL in red (R), yellow (Y), green (G) and blue (B).

(b) Resulting polarization contrast as a function of angle from measured angular distribution of a grating described by comparative experiment A.

FIG. 3

Transmission mode recording geometry with two beams. The resulting grating and the grating-vector K (perpendicular to the grating direction) are indicated.

FIG. 4

Measured angular distribution of P, S and un-polarized light of the grating described in comparative experiment B.

FIG. 5

(a) Measured angular distribution of S- and P-polarized light for red (611 nm), green (546 nm), and blue (436 nm) wavelengths, highlighting collimation and angular dispersion.

(b) Angular distribution of forward and backward emitted light for red.

(c) Angular distribution of P- and S-polarized light for red (R), green (G), and blue (B) wavelengths.

1. Edge-lit slab waveguide equipped with a slanted anisotropic holographic layer which couples out linearly polarized light.

2. Waveguide according to claim 1, having a polarization contrast of at least 3.

3. Waveguide according to claim 1, wherein the light of different wavelengths (colors) is coupled out at different angles.

4. Waveguide according to claim 3 with a degree of polarization of at least 3 at all visible wavelengths.

5. Waveguide according to claim 1, wherein the light which is not outcoupled can be recycled.

6. Slanted anisotropic holographic layer based on photo-polymerizable material and at least one mesogen in which the mesogen is in an aligned state after polymerization.

7. Layer according to claim 6, wherein the layer is based on at least one reactive monomer and at least one non-reactive mesogen in which the mesogen is in an aligned state after polymerization of the monomer.

8. Layer according to claim 6, wherein the layer is based on at least one reactive monomer and at least one reactive mesogen in which the mesogen is in an aligned state after polymerization.

9. Layer according to claim 6, wherein the layer comprises at least one reactive monomer and a mixture of at least one reactive and at least one non-reactive mesogen which mesogens are in an aligned state after polymerization.

10. Waveguide according to claim 1, comprising a slanted anisotropic holographic layer based on photo-polymerizable material and at least one mesogen in which the mesogen is in an aligned state after polymerization.

11. Edge-lit slab waveguide equipped with a slanted anisotropic holographic layer which couples out linearly polarized light, wherein the layer is obtained by polymerization of a mixture of at least one reactive monomer and a mesogen, and wherein the mesogen is in an aligned state.

12. Waveguide according to claim 11, wherein the mesogen comprises at least one compound having a polymerizable group.

13. Waveguide according to claim 11, wherein the reactive monomer comprises at least a polyfunctional acrylate or methacrylate compound.

14. Waveguide according to claim 11, wherein the mesogen comprises at least one compound having a cationically polymerizable group.

15. Waveguide according to claim 14, wherein the mesogen comprises at least one compound having an epoxy, oxetane or vinylether group.

16. Waveguide according to claim 1, the difference between the ordinary refractive index of the mesogen (n_{o,m}) and the isotropic refractive index of the polymer (n_{iso,p}) being less than 0.03 in the state wherein polarized light is outcoupled or the difference between the extra-ordinary refractive index of the mesogen (n_{e,m}) and the isotropic refractive index of the polymer (n_{iso,p}) being less than 0.03 in the state wherein polarized light is outcoupled.

17. Waveguide according to claim 1 comprising at least one non-reactive mesogen, wherein the coating or layer is switchable between a light out-coupling (bright) state and a non-light-outcoupling (dark) state.

18. Method for producing a slanted anisotropic holographic layer, based on at least one reactive monomer and at least one reactive mesogen which are polymerized by use of different polymerization methods.

19. Method according to claim 18, wherein the polymerization of the monomer is induced using a photo-initiator and UV light and in which the hologram is recorded in transmission mode.

20. Slanted anisotropic holographic layer obtainable by the method according to claim 18.

21. Edge-lit slab waveguide comprising a slanted anisotropic holographic layer according to claim 20.

22. Frontlight comprising the waveguide according to claim 1.

23. Backlight comprising the waveguide according to claim 1.

24. Display comprising a waveguide according to claim 1.

25. Optical device comprising a waveguide according to claim 1.

26. Method for making a slanted anisotropic holographic layer comprising the steps of
a) providing a mixture of at least one reactive monomer and a reactive mesogen,
b) making a layer of the mixture,
c) applying UV radiation in order to at least partially polymerize the reactive monomer into a slanted transmission grating,
d) applying a subsequent thermal or UV exposure to further polymerize the reactive mesogen and (optional) residual unreacted monomer.

27. The method according to claim 26, wherein the UV radiation in step c is applied using a laserbeam split into a two beam transmission mode geometry.

28. The method according to claims 26, wherein the reactive monomer comprises at least a polyfunctional acrylate or methacrylate compound.

29. The method according to claim 26, wherein the reactive mesogen comprises at least a compound having a cationically polymerizable group.

30. The method according to claim 26, wherein the layer of the mixture is prepared by filling the mixture into a cell having one or more spacers of a defined thickness.
